(19) United States
(12) Patent Application Publication
(10) Pub. No.: US 2008/0219083 A1
(43) Pub. Date: Sep. 11, 2008

(54) Semiconductor memory device and power control method thereof

(76) Inventor: Shih-Chieh Chang, Hsin-Chu City (TW)

Correspondence Address: TROXELL LAW OFFICE PLLC, SUITE 1404, 5205 LEESBURG PIKE, FALLS CHURCH, VA, 22041, US

(21) Appl. No.: 12/073,507

(22) Filed: Mar. 6, 2008

(30) Foreign Application Priority Data
Mar. 9, 2007 (TW) 096108136

(51) Int. Cl. G11C 8/18

(52) U.S. Cl. 365/233.1

(57) ABSTRACT

A semiconductor memory device for saving power consumption and control method thereof are disclosed. The clock frequency on memory chips is dynamically adjusted to match the data transferring rate between the other units in computer system and the memory chips. A fill state of buffer and transferring rate on an input/output interface are detected by a monitor. A frequency adjuster increases or decrease the clock frequency on memory chips for keeping a good transferring rate and saving unnecessary power according to the monitor's detection.

### BACKGROUND OF THE INVENTION

1. Field of the Invention

This invention relates to a semiconductor memory device and, more particularly, to a semiconductor memory device whose buffer storing capability and transferring rate is monitored in order to dynamically control the clock frequency of memories for power saving.

2. Description of the Prior Art

Semiconductor memory devices are popular storage devices in computer system. Data is stored in memory chips and written or read by a current/voltage supply. In order to commute with other units in computer system, the current/voltage supply is synchronized by a clock signal. High speed memory devices usually have higher clock frequency for communication with high speed units in computer system. Because the clock frequencies and phase between semiconductor memory device and other units are different, a buffer for temporary storing is necessary for synchronization. In a conventional semiconductor device A with a controller B and a set of memory chips C, the data access from other units in computer system goes through an input/output interface B1 first. For events of read or writing access, a read/writing command is sent to a memory control element B2 to inform the memory chips C where to read or write. And, a buffer-stored data is arranged between buffer, the memory chips C, and the input/output interface B1 by a buffer management element B3. The input/output interface B1, memory control element B2 and buffer management element B3 are included in the controller B and managed by a micro processing element B4 which has an electrical connection to Read Only Memory or Random Access Memory (ROM/RAM).

In the conventional memory device A, the external clock and the internal clock for reading from and writing to the memory chips is fixed. As well known in the art, a higher clock frequency consumes a higher level of electrical power. Because the clock frequency is always the same no matter how busy the data access is, lot wasting power is dumped to dealing with small amount of data access.

For saving some power in the conventional memory device A, a switching clock corresponding to working stages of computer system is given. The clock frequency is switched to a lower level or an off mode when the working stage of computer system is set as “Standby Mode” or “Hibernation Mode”. The “Standby Mode” or “Hibernation Mode” is set by computer system after a certain idle time (no data access in long period). However, in most using situations, large amount and small amount of data access are alternate frequently. The switching period between “Normal Mode” and “Standby Mode” or “Hibernation Mode” is too large to response the real situations of using. The portion of saving power by switching clock frequency in conventional memory device A is small because the large switching period.

### SUMMARY OF THE INVENTION

Because the power saving in conventional semiconductor memory device is not so efficient for the large switching period, an object of the present invention is to provide a control method for semiconductor memory device with dynamically switching clock disclosed in the present invention. A buffer storing capability is monitored all the time, in order to control a proper clock frequency for memory chips. The buffer storing capability likes a jam indicator which is disclosed in the present invention to show the speed of memory chips is relatively high or low to the external speed.

Another object of the present invention is to provide a semiconductor memory device which has a monitor element and frequency adjuster element is disclosed in the present invention. The monitor element monitors the buffer storing capability for increasing or decreasing clock frequency of memory chips through the frequency adjuster element. Because the monitor of monitor element and the control of frequency adjuster element are all dynamical, power allocation is instantaneous too in order to save more power in semiconductor memory device.

A control method for semiconductor memory device in the present invention comprises the following steps: (a) providing a controller to control data access between the other units in computer system and the memory chips; (b) providing a monitor to monitor data transferring rate between the other units in computer system and the memory chips; and (c) providing a frequency adjuster to increase or decrease clock frequency of the controller for data access speed on memory chips.

A semiconductor memory device with a controller and a set of memory chips in the present invention comprises: (a) an input/output interface; (b) a memory control element; (c) a buffer management element; (d) a micro processing element; (e) a monitor element; and (f) a frequency adjuster element. The input/output interface has one or plurality of electrical connections to other units in computer system for accepting data access commands and transferring data. The memory control element has electrical connections to the memory chips and the input/output interface in order to control data transfer between the other units in computer system and the memory chips. The buffer management element has electrical connections to the input/output interface, the memory control element and a buffer in order to control buffer-stored data transferring. The micro processing element has electrical connections to the input/output interface, the memory control element, the buffer management element and one or plurality of Read Only Memories (ROM) or Random Access Memories (RAM) in order to provide an overall control. The monitor element monitors the buffer storing capability in order to inform data transferring rate on the buffer to the frequency adjuster element. According to the data transferring rate, frequency adjuster element controls the controller's clock frequency for speeding up or slowing down the data access on memory chips.

For a more complete understanding of the features and advantages of the present invention, reference is now made to the following description taken in conjunction with accompanying drawings, in which:

### BRIEF DESCRIPTION OF THE DRAWINGS

FIG. 1 shows a flow chart of a control method for semiconductor memory device in the present invention.

FIG. 2 shows a circuit chart for first embodiment of semiconductor memory device in the present invention.

FIG. 3 shows a circuit chart for second embodiment of semiconductor memory device in the present invention.

FIG. 4 shows a conventional semiconductor memory device with a controller and a set of memory chips.

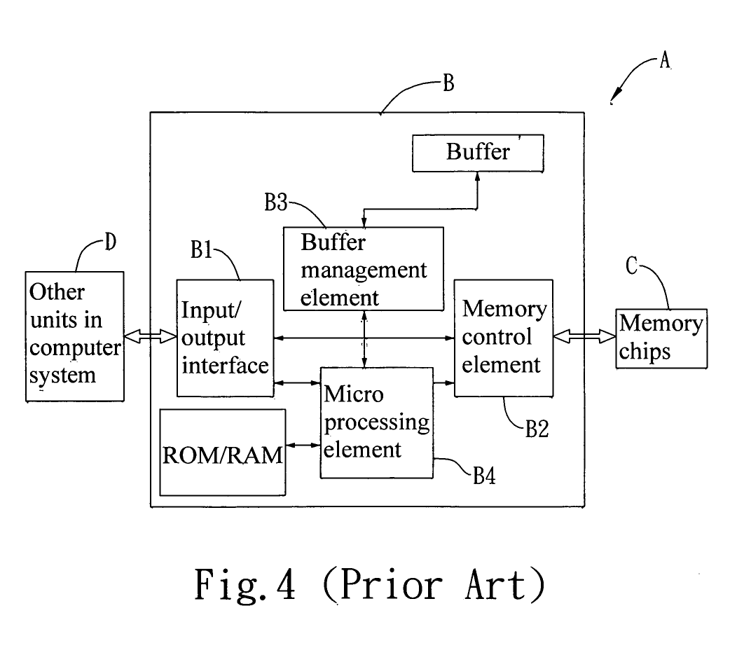

### DETAILED DESCRIPTION OF THE PREFERRED EMBODIMENTS

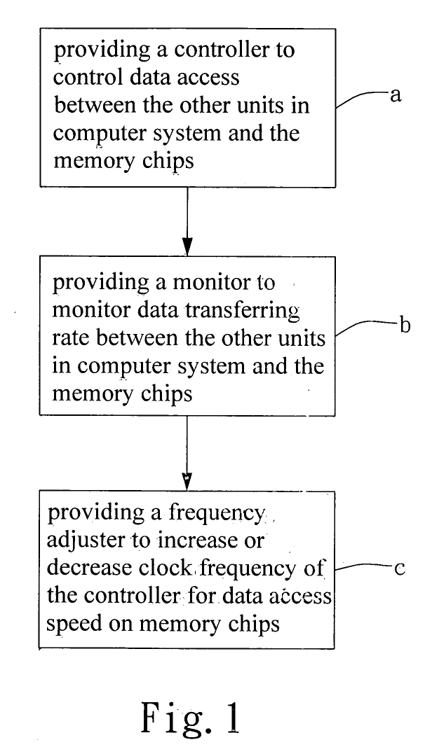

As shown in FIG. 1, a control method for data access to semiconductor memory device with memory chips in the present invention comprises the following steps:

(a) providing a controller to control data access between the other units in computer system and the memory chips;

(b) providing a monitor to monitor data transferring rate between the other units in computer system and the memory chips; and

(c) providing a frequency adjuster to increase or decrease clock frequency of the controller for data access speed on memory chips.

According to step (b), the data transferring rate between the other units in computer system and the memory chips is monitored by measuring a fill state of buffer which stores temporary data at event of read or writing access to memory chips. In step (c), the fill state of buffer is reported to the frequency adjuster for increasing or decreasing the clock frequency.

The further description of the monitor and frequency adjuster is represented by introducing a first embodiment of semiconductor memory device in the present invention.

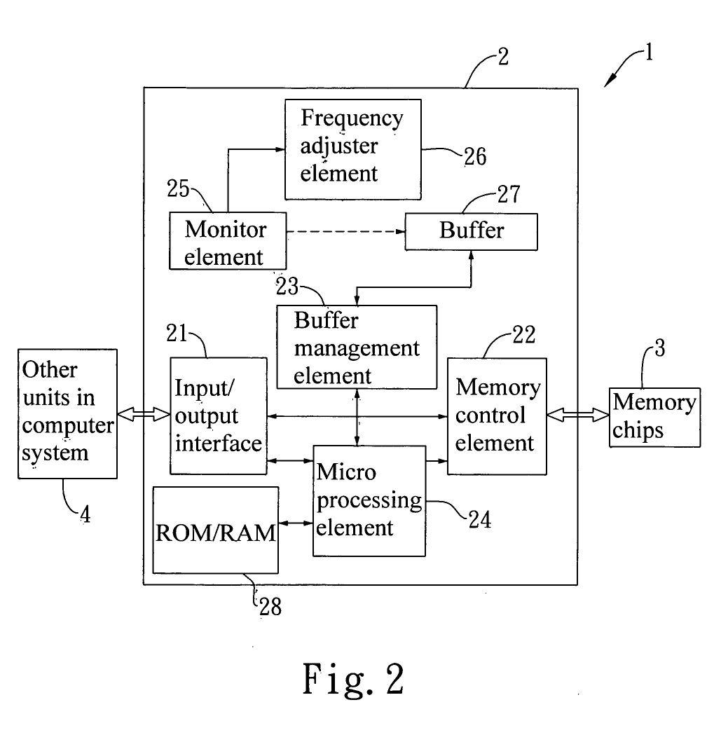

As FIG. 2 shown, the first embodiment of semiconductor memory device 1 with a controller 2 and a set of memory chips 3 in the present invention. The controller 2 comprises: an input/output interface 21; a memory control element 22; a buffer management element 23; a micro processing element 24; a monitor element 25; and a frequency adjuster element 26.

The input/output interface 21 has one or a plurality of electrical connections to the other units 4 in computer system for accepting data access from the other units. The memory control element 22 has electrical connections to the input/output interface 21 and the memory chips 3 for data access to the other units 4. The buffer management element 23 has electrical connections to a buffer 27, the input/output interface 21 and the memory control element 22 in order to control buffer-stored data transferring of buffer 27. The micro processing element 24 has electrical connections to the input/output interface 21, the memory control element 22, the buffer management element 23 and one or a plurality of Read Only Memories (ROM) or Random Access Memories (RAM) 28 in order to provide an overall control. The monitor element 25 monitors the buffer storing capability in order to inform data transferring rate on the buffer 27 to the frequency adjuster element 26. In the first embodiment of semiconductor memory device for the present invention, the fill state of buffer 27 is detected for monitoring the buffer storing capability. The frequency adjuster element 26 has electrical connection to the monitor element 25 in order to change clock frequency on the memory chips 3 according to the fill state of buffer. A clock generator (not shown) can accept the changing frequency information from the frequency adjuster element 26 to speed up or slow down the data transferring rate on the memory chips 3.

When the data access is read access or writing access, the action of frequency adjuster element 26 is different according to the fill state of buffer.

For event of writing access in first embodiment, a critical lower state for fill state (e.g. ¼ full capacity) is set. When the monitor element 25 senses fill state of buffer is always below the critical lower state in a certain period, it represents data transferring rate from the buffer 27 to the set of memory chips 3 is faster than writing rate from the other units in computer system to the buffer 27. Therefore, the clock generator (not shown) is informed by the frequency adjuster element 26 to decrease the clock frequency of the set of memory chips 3. And, the writing speed for the memory chips 3 is slowed down for saving electrical power under the small amount of writing access. On the other hand, a critical upper state for fill state (e.g. ¾ full capacity) is set for event of writing access. When the monitor element 25 senses fill state of buffer is always above the critical upper state in a certain period, it represents data transferring rate from the buffer 27 to the set of memory chips 3 is slower than writing rate from the other units in computer system to the buffer 27. Therefore, the clock generator (not shown) is informed by the frequency adjuster element 26 to increase the clock frequency of the set of memory chips 3. And, the writing speed for the memory chips 3 is speeded up under the large amount of writing access.

For event of read access in first embodiment, a critical lower state for fill state (e.g. ¼ full capacity) is set. When the monitor element 25 senses fill state of buffer is always below the critical lower state in a certain period, it represents data transferring rate from the set of memory chips 3 to the buffer 27 is slower than reading rate from the buffer 27 to the other units in computer system. Therefore, the clock generator (not shown) is informed by the frequency adjuster element 26 to increase the clock frequency of the set of memory chips 3. And, the reading speed for the memory chips 3 is speeded up under the large amount of reading access. On the other hand, a critical upper state for fill state (e.g. ¾ full capacity) is set for event of reading access. When the monitor element 25 senses fill state of buffer is always above the critical upper state in a certain period, it represents data transferring rate from the set of memory chips 3 to the buffer 27 is faster than reading rate from the buffer 27 to the other units in computer system. Therefore, the clock generator (not shown) is informed by the frequency adjuster element 26 to decrease the clock frequency of the set of memory chips 3. And, the reading speed for the memory chips 3 is slowed down for saving electrical power under the small amount reading access.

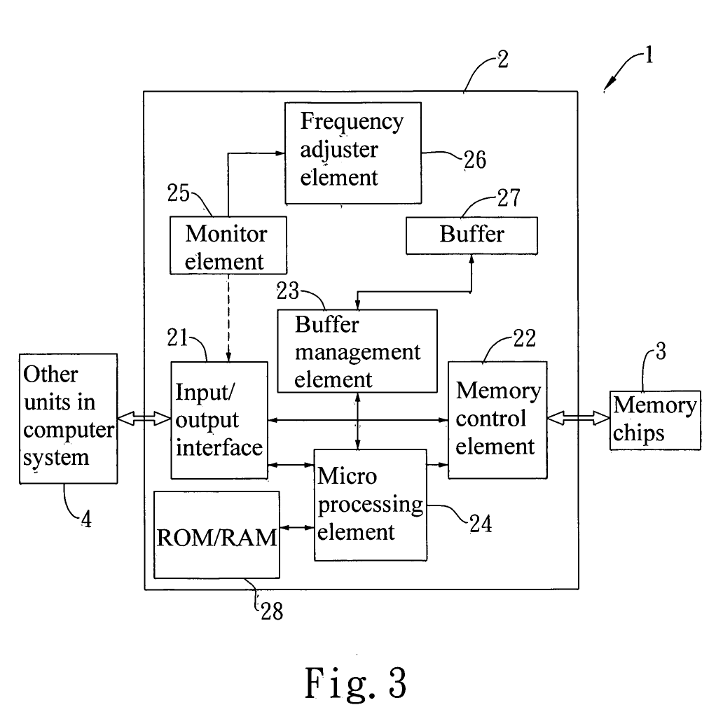

The monitor element 25 has electrical connection to the input/output interface 21 to monitor the data transferring rate on the input/output interface 21 in a second embodiment. The circuit chart for second embodiment of semiconductor memory device in the present invention is shown in FIG. 3. According to the transferring rate, the frequency adjuster element 26 informs the clock generator (not shown) to change clock frequency on the memory chips 3.

The frequency adjuster element 26 in the second embodiment can be a frequency divider. When the transferring rate on the input/output interface 21 is slow, the clock frequency generated from the clock generator (not show) is divided by two for saving electrical power; on the contrary, the clock frequency generated from the clock generator (not shown) is multiplied by two while the transferring rate on the input/output interface 21 is fast.

The frequency adjuster 26 also comprises a Phase Lock Loop (PLL) frequency synthesizer in order to match the external clock and internal clock (which clock on the memory chips 3) in same phase. It can help to pass data more precisely and save more electrical power.

Accordingly, the semiconductor memory device with dynamically changed clock frequency in the present invention can save the more electrical power than the conventional memory device with long switching period. The fill state of buffer is a convenient indicator for adjusting clock frequency on time. The frequency adjusting can be in many forms depending on the circuits of controller in memory device. The buffer may be not included in the controller.

It should be understood that different modifications and variations could be made from the disclosures of the present invention by the people familiar in the art, which should de deemed without departing the spirit of the present invention.

What is claimed is:

1. A control method of semiconductor memory device for saving electrical power comprises the following steps:
(a) providing a controller to control data access between the other units in computer system and the memory chips;
(b) providing a monitor to monitor data transferring rate between the other units in computer system and the memory chips; and
(c) providing a frequency adjuster to increase or decrease clock frequency of the controller for data access speed on memory chips.

2. A control method of semiconductor memory device according to claim 1, wherein the monitor monitors a buffer whose input and output situations are detected to represent the state of transferring rate.

3. A control method of semiconductor memory device according to claim 2, wherein the monitor monitors a buffer whose fill state is detected to represent the state of transferring rate

4. A control method of semiconductor memory device according to claim 2, wherein the frequency adjuster to increase or decrease clock frequency according to the input and output situations of buffer.

5. A control method of semiconductor memory device according to claim 1, wherein the monitor monitors the data transferring rate from the other units in computer system to the semiconductor memory device.

6. A control method of semiconductor memory device according to claim 5, wherein the frequency adjuster to increase or decrease clock frequency according to the data transferring rate from the other units in computer system to the semiconductor memory device.

7. A semiconductor memory device with a controller and a set of memory chips comprises:
(a) an input/output interface with one or a plurality of electrical connections to other units in computer system for accepting data access commands and transferring data;
(b) a memory control element with electrical connections to the memory chips and the input/output interface in order to control data transfer between the other units in computer system and the memory chips;
(c) a buffer management element with electrical connections to the input/output interface, the memory control element and a buffer in order to control buffer-stored data transferring;
(d) a micro processing element with electrical connections to the input/output interface, the memory control element, the buffer management element and one or plurality of Read Only Memories (ROM) or Random Access Memories (RAM) in order to provide an overall control for the semiconductor memory device;
(e) a monitor element monitoring situations of data access; and
(f) a frequency adjuster element with electrical connection to the monitor element for controlling the controller's clock frequency in order to speed up or slow down the data transferring rate on memory chips according to the monitor element's detection.

8. A semiconductor memory device according to claim 7, wherein the monitor element has electrical connection to a buffer whose input and output situation is detected by the monitor element.

9. A semiconductor memory device according to claim 8, wherein the fill state of buffer is detected by the monitor element.

10. A semiconductor memory device according to claim 8, wherein the frequency adjuster element increases or decrease the controller's clock frequency on the memory chips according to the input and output situation of buffer.

11. A semiconductor memory device according to claim 7, wherein the monitor element has electrical connection to the input/output interface whose data transferring rate is detected by the monitor element.

12. A semiconductor memory device according to claim 11, wherein the frequency adjuster element increases or decrease the controller's clock frequency on the memory chips according to the data transferring rate on input/output interface.

13. A semiconductor memory device according to claim 7, wherein the frequency adjuster element comprises a frequency divider.

14. A semiconductor memory device according to claim 7, wherein the frequency adjuster element comprises a Phase Lock Loop (PLL).

15. A semiconductor memory device according to claim 14, wherein the Phase Lock Loop (PLL) is a Phase Lock Loop (PLL) frequency synthesizer.
